(19) United States
(12) Patent Application Publication
(10) Pub. No.: US 2024/0249051 A1
(43) Pub. Date: Jul. 25, 2024

(54) MEMORY DEVICE, ELECTRONIC DEVICE, AND OPERATING METHOD OF MEMORY DEVICE FOR VOTING VALID SIGNAL

(71) Applicant: Samsung Electronics Co., Ltd., Suwon-si (KR)

(72) Inventors: Sungoh Ahn, Suwon-si (KR); Jaewon Park, Suwon-si (KR)

(21) Appl. No.: 18/449,304

(22) Filed: Aug. 14, 2023

(30) Foreign Application Priority Data
Jan. 25, 2023 (KR) 10-2023-0009735

(51) Int. Cl. G06F 30/327

(52) U.S. Cl. CPC G06F 30/327

(57) ABSTRACT

Disclosed is a memory device, which includes a logic circuit that receives a first signal and a second signal from an external host, an output circuit that receives a first logic operation result or a second logic operation result from the logic circuit, a first logic gate that receives the first signal or the second signal and performs a third logic operation to output a third signal, a second logic gate that receives the first signal and the second signal and performs a fourth logic operation to output a fourth signal, and a multiplexer that receives the third signal and the fourth signal, receives the first logic operation result or the second logic operation result from the output circuit, and outputs one of the third signal and the fourth signal as a fifth signal in response to the first or second logic operation results.

### CROSS-REFERENCE TO RELATED APPLICATIONS

This application claims priority under 35 U.S.C. § 119 to Korean Patent Application No. 10-2023-0009735, filed on Jan. 25, 2023, in the Korean Intellectual Property Office, the disclosures of which are incorporated by reference herein in their entireties.

### BACKGROUND

Embodiments of the present disclosure described herein relate to a semiconductor device, and more particularly, relate to a memory device, an electronic device, and an operating method of the memory device for voting a valid signal from among signals applied to multi-pins.

To improve transmission and reception of signals, memory devices additionally transmit and receive the same spare signals to and from a host for each of a command signal, an address signal, a data signal, and a test signal through a plurality of spare channels.

However, various errors may occur in at least one channel among a plurality of channels in the memory devices. The memory devices may not be able to normally transmit/receive signals with the host through the channel in which an error is occurred.

In this case, it may be difficult for the memory device to accurately vote the channel providing a valid signal, according to an error type among various errors. Therefore, techniques of flexibly voting the channel providing the valid signal, according to an error type may be needed.

### SUMMARY

Embodiments of the present disclosure provide a memory device capable of flexibly voting valid signals from among a plurality of signals received from a host even if an error occurs in some of multi-pins, an electronic device, and a method of operating the memory device.

According to some embodiments of the present disclosure, a memory device includes a logic circuit configured to receive a first signal and a second signal from an external host and configured to perform a first logic operation or a second logic operation based on an initial value of the second signal, an output circuit configured to receive a first logic operation result or a second logic operation result from the logic circuit and configured to store the first logic operation result or the second logic operation result that was received, in response to a reset signal, a first logic gate that receives the first signal and the second signal and configured to perform a third logic operation on the first signal and the second signal to output a third signal, a second logic gate configured to receive the first signal and the second signal and configured to perform a fourth logic operation on the first signal and the second signal to output a fourth signal, and a multiplexer configured to receive the third signal and the fourth signal, configured to receive the first logic operation result or the second logic operation result that was stored from the output circuit, and configured to output the third signal or the fourth signal as a fifth signal in response to the first logic operation result or the second logic operation result that was received by the multiplexer.

According to some embodiments of the present disclosure, a method of operating a memory device including a logic circuit, an output circuit, a first logic gate, a second logic gate, and a multiplexer includes receiving, by the logic circuit, a first signal and a second signal from an external host, performing, by the logic circuit, a first logic operation or a second logic operation on the first signal or the second signal respectively based on an initial value of the second signal, receiving, by the output circuit, an operation result from the logic circuit, and storing the operation result in response to a reset signal, outputting, by the first logic gate, a third signal by performing a third logic operation on the first signal and the second signal, outputting, by the second logic gate, a fourth signal by performing a fourth logic operation on the first signal and the second signal, and outputting, by the multiplexer, the third signal or the fourth signal as a fifth signal in response to the operation result.

According to some embodiments of the present disclosure, an electronic device includes an external host and a memory device configured to receive a first signal and a second signal from the external host, and the memory device includes a logic circuit that performs a first logic operation or a second logic operation based on an initial value of the second signal, an output circuit that receives a first logic operation result or a second logic operation result from the logic circuit and configured to store the first logic operation result or the second logic operation result in response to a reset signal, a first logic gate that performs a third logic operation on the first signal and the second signal to output a third signal, a second logic gate that performs a fourth logic operation on the first signal and the second signal to output a fourth signal, and a multiplexer configured to receive the third signal and the fourth signal, configured to receive the first logic operation result or the second logic operation result that was stored from the output circuit, and configured to output the third signal or the fourth signal as a fifth signal in response to the first logic operation result or the second logic operation result that was received by the multiplexer.

### BRIEF DESCRIPTION OF THE FIGURES

A detailed description of each drawing is provided to facilitate a more thorough understanding of the drawings referenced in the detailed description of the present disclosure.

FIG. 1 is a diagram illustrating an electronic device, according to some embodiments of the present disclosure.

FIG. 2 is a diagram illustrating a configuration of a logic die included in an electronic device.

FIG. 3 is a diagram illustrating a detailed configuration of a voting circuit included in a logic die.

FIG. 4A is a timing diagram illustrating a first embodiment of outputting a valid signal when an initial value is a first logic value.

FIG. 4B is a timing diagram illustrating a second embodiment of outputting a valid signal when an initial value is a first logic value.

FIG. 4C is a timing diagram illustrating a third embodiment of outputting a valid signal when an initial value is a first logic value.

FIG. 5A is a timing diagram illustrating a first embodiment of outputting a valid signal when an initial value is a second logic value.

FIG. 5B is a timing diagram illustrating a second embodiment of outputting a valid signal when an initial value is a second logic value.

FIG. 5C is a timing diagram illustrating a third embodiment of outputting a valid signal when an initial value is a second logic value.

FIG. 6 is a diagram illustrating a detailed configuration of a memory device, according to some embodiments of the present disclosure.

FIG. 7 is a flowchart illustrating an operating method for outputting a valid signal by a memory device.

### DETAILED DESCRIPTION

Hereinafter, embodiments of the present disclosure may be described in detail and clearly to such an extent that an ordinary one in the art easily implements the present disclosure.

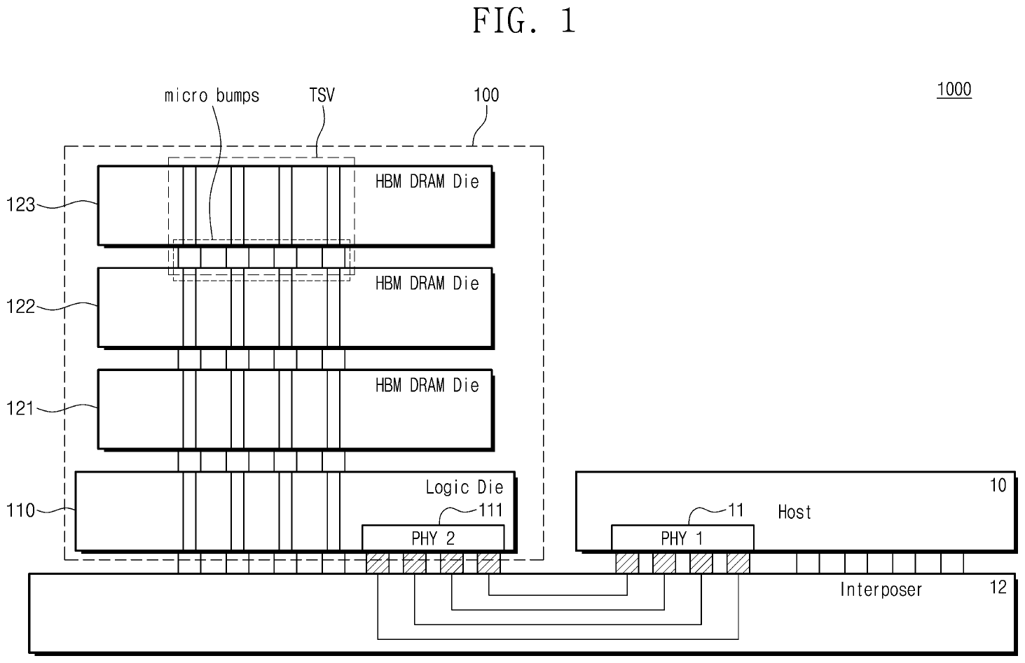

FIG. 1 is a diagram illustrating an electronic device 1000, according to some embodiments of the present disclosure. Referring to FIG. 1, the electronic device 1000 may include a memory device 100, a host 10, and an interposer 12.

The memory device 100 may include first to third memory dies (HBM DRAM Dies) 121 to 123 and a logic die 110. The first to third memory dies 121 to 123 may be sequentially stacked on the logic die 110 in a perpendicular direction, and/or on the interposer 12.

The first to third memory dies 121 to 123 and the logic die 110 may be electrically connected to each other by through silicon vias (hereinafter referred to as TSVs) and micro bumps arranged in a matrix form. However, locations of the through silicon vias and the micro bumps are not limited to illustration of FIG. 1.

The first to third memory dies 121 to 123 may be identically manufactured of each other. In FIG. 1, the number of first to third memory dies 121 to 123 is illustrated as three, but the number of memory dies is not limited thereto. Here, the memory die may be referred to as a “core die”, a “slave die”, etc., and a die may be referred to as a “chip”.

The logic die 110 may communicate with a device located outside the memory device 100. For example, the device to which the logic die 110 communicates may be the host 10. Here, the host 10 may be referred to as a System on Chip (SoC). The logic die 110 may include a second physical layer (PHY 2) 111 electrically connected to (PHY 1) 11 of the host 10, and may communicate with the host 10 based on the second physical layer (PHY 2) 111.

The logic die 110 may transmit addresses and data received from the host 10 to the first to third memory dies 121 to 123. The logic die 110 may receive data from the first to third memory dies 121 to 123.

The logic die 110 may provide an interface between the first to third memory dies 121 to 123 and the host 10. The logic die 110 may be referred to as an “interface die”, a “master die”, a “buffer die”, etc.

The memory device 100 may be a general-purpose dynamic random access memory (DRAM) device such as a double data rate synchronous DRAM (DDR SDRAM) device, a DDR2 SDRAM device, a DDR3 SDRAM device, a DDR4 SDRAM device, a DDR5 SDRAM device, etc. The memory device 100 may be a mobile DRAM device such as a low power double data rate (LPDDR) SDRAM device, an LPDDR2 SDRAM device, an LPDDR3 SDRAM device, an LPDDR4 SDRAM device, an LPDDR4X SDRAM device, an LPDDR5 SDRAM device, etc. However, the memory device 100 illustrated in FIG. 1 is not limited thereto.

The host 10 may include a processor (not illustrated) capable of performing various operations for applications supported by the electronic device 1000. For example, the host 10 may include at least one of a central processing unit (CPU), an image signal processing unit (ISP), a digital signal processing unit (DSP), a graphics processing unit (GPU), a vision processing unit (VPU), and a neural processing unit (NPU).

The host 10 may include a first physical layer (PHY 1) 11 electrically connected to the logic die 110, and may communicate with the logic die 110 based on the first physical layer (PHY 1) 11. The host 10 may store data that may be needed for an operation to the memory device 100 or may read data needed for an operation from the memory device 100.

The interposer 12 may connect the memory device 100 to the host 10. In more detail, the interposer 12 may connect between the memory device 100 and the host 10 and may provide physical paths which are formed of conductive materials for an electrical connection. For example, the interposer 12 may be a silicon interposer. However, the interposer 12 illustrated in FIG. 1 is not limited thereto.

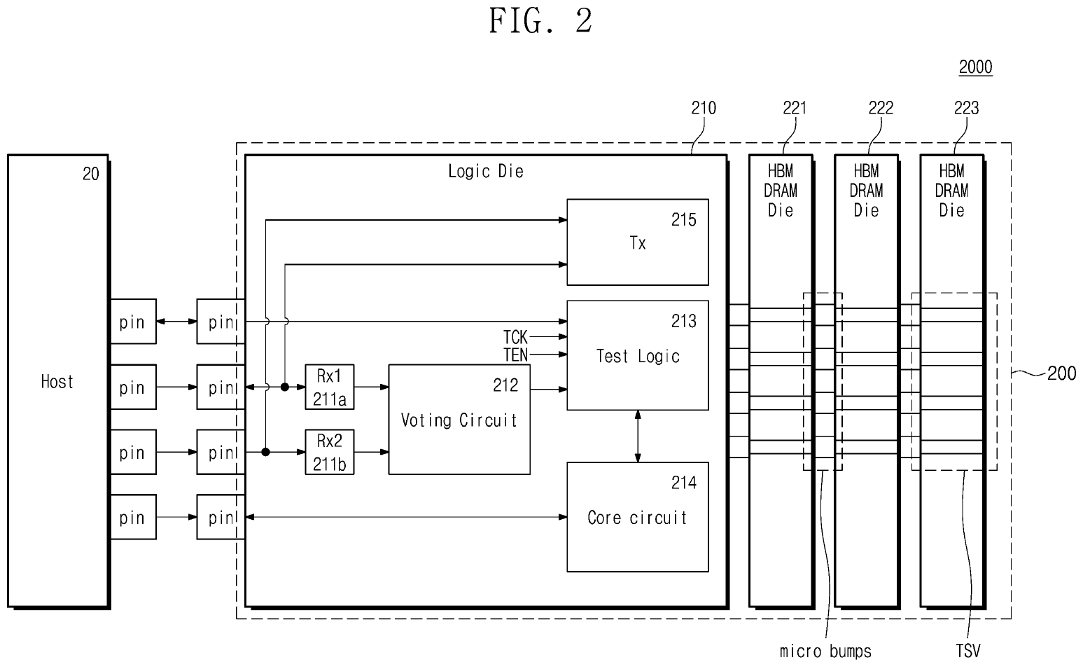

FIG. 2 is a diagram illustrating a configuration of a logic die included in an electronic device. As an example, FIG. 2 illustrates a configuration in which four pins connected to a host 20 transmit and receive signals to and from four pins connected to a logic die 210, respectively. However, the number of pins connected to the host 20 and the logic die 210 may be five or more.

Referring to FIGS. 1 and 2, an electronic device 2000 may include a memory device 200 and the host 20. The hosts 10 or 20 may transmit a plurality of signals to the memory device 200 through pins connected to the hosts 10 or 20.

The memory device 200 may include the logic die 210 and first to third memory dies 221 to 223. For example, locations of the first to third memory dies 221 to 223, through silicon vias (TSVs), and micro bumps of FIG. 2 may correspond to locations of the first to third memory dies 121 to 123, the through silicon vias (TSVs), and the micro bumps of FIG. 1. Therefore, additional descriptions of similar components and similar operations will be omitted to avoid redundancy.

The logic dies 110 and 210 may include a first receiver (Rx1) 211a, a second receiver (Rx2) 211b, a voting circuit 212, test logic 213, a core circuit 214, and a transmitter (Tx) 215.

The first receiver (Rx1) 211a and the second receiver (Rx2) 211b may receive a plurality of signals through multi-pins. The first receiver (Rx1) 211a and the second receiver (Rx2) 211b may transmit a plurality of signals to the voting circuit 212.

The voting circuit 212 may receive multi-signals from the first receiver (Rx1) 211a and the second receiver (Rx2) 211b. Multi-signals transmitted from the hosts 10 or 20 may be the same signals as the multi-signals received to the voting circuit 212. The voting circuit 212 may output one of the multi-signals to the test logic 213. A detailed description of the configuration of the voting circuit 212 will be described later.

The test logic 213 may receive a test input signal through a pin connected to the logic dies 110 and/or 210. The test input signal may be a signal for testing the test logic 213 itself or signals received by the test logic 213.

The test logic 213 may receive a test clock signal TCK and a test enable signal TEN. The test logic 213 may decode and store the test clock signal TCK and the test enable signal TEN.

When the test logic 213 is activated by the test enable signal TEN, a value of the test input signal applied to the test logic 213 at a rising edge or falling edge of the test clock signal TCK may be stored.

When the signal received from the voting circuit 212 is normal, the test logic 213 may output a test output signal including information indicating that at least one of the multi-pins is normal to the hosts 10 or 20 through a pin connected to the logic dies 110 and 210. In this case, the test logic 213 may output the signal received from the voting circuit 212 to the core circuit 214 as a valid signal.

When the signal received from the voting circuit 212 is abnormal, the test logic 213 may output a test output signal including information indicating that all of the multi-pins are faulty pins to the hosts 10 or 20 through a pin connected to the logic dies 110 and 210. In this case, the test logic 213 may detect faulty pins based on the test input signal and the signal received from the voting circuit 212.

For example, when all of the multi-pins are faulty pins, the signal received by the test logic 213 may be a signal having a fixed value of 0 or 1. A detailed description of the signal received by the test logic 213 will be described later.

The core circuit 214 may execute an operation corresponding to a valid signal. For example, when the valid signal includes a read command, the core circuit 214 may output data to the hosts 10 or 20 through a pin connected to the logic dies 110 and/or 210.

For example, when the valid signal is a write command, the core circuit 214 may receive data from the hosts 10 or 20 through a pin connected to the logic dies 110 and/or 210.

The transmitter 215 may receive multi-signals through multi-pins connected to the logic dies 110 and/or 210. The transmitter 215 may transmit the multi-signals to the first to third memory dies 221 to 223.

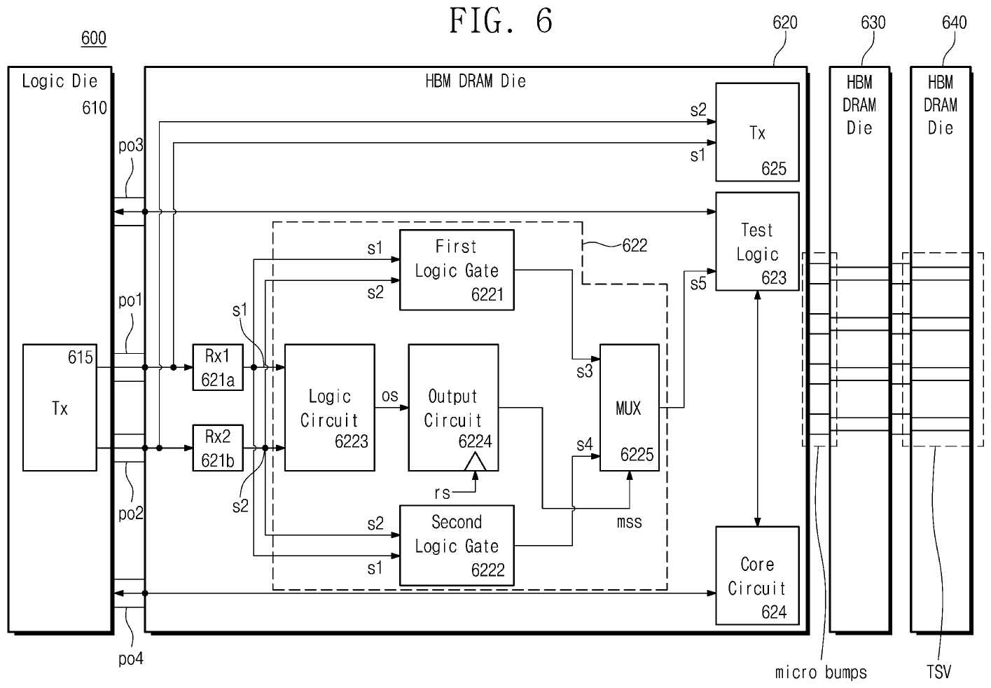

One memory die among the first to third memory dies 221 to 223 may include the same or similar components as those included in the logic dies 110 and 210. In this case, one memory die may flexibly vote valid signals similarly to logic dies 110 and 210. A description of the case where the components are included in the memory die will be described later with reference to FIG. 6.

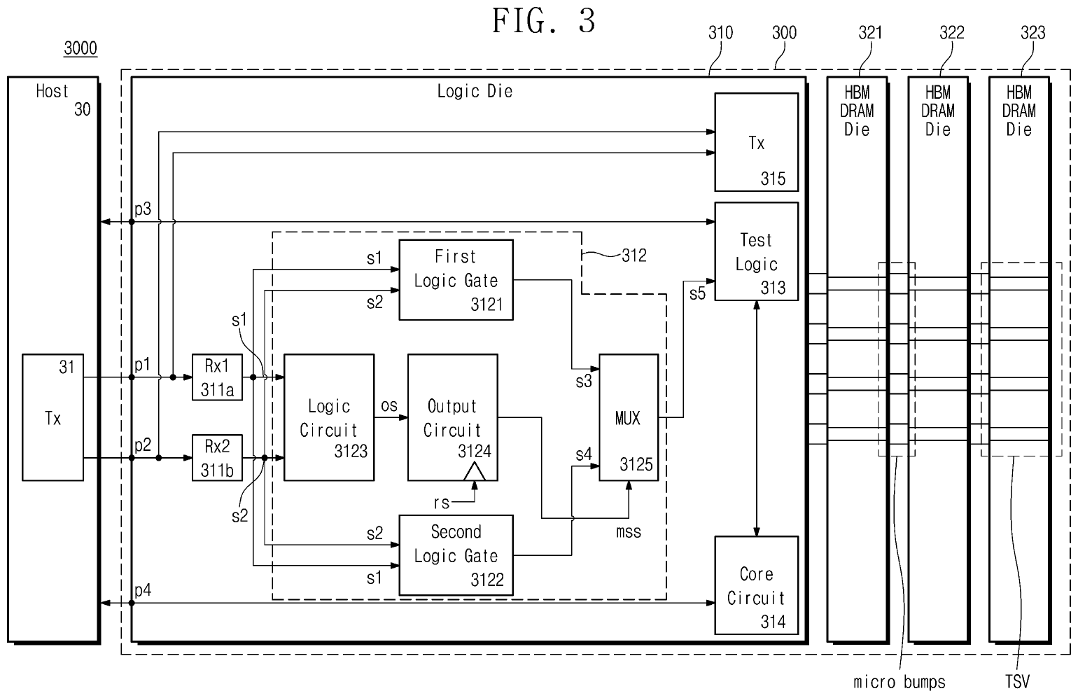

FIG. 3 is a diagram illustrating a detailed configuration of a voting circuit included in a logic die. As an example, FIG. 3 illustrates a configuration in which four pins connected to a host 30 transmit and receive signals to and from four pins connected to a logic die 310, respectively. However, the number of pins connected to the host 30 and the logic die 310 may be five or more.

Referring to FIGS. 2 and 3, an electronic device 3000 may include a memory device 300 and the host 30.

The host 30 may include a transmitter (Tx) 31. The transmitter (Tx) 31 may transmit a first signal s1 and a second signal s2 to the logic die 310 through a first pin p1 and a second pin p2. The first signal s1 and the second signal s2 may be the same or similar signals, in some embodiments. The first signal s1 and the second signal s1 may be one of command, address, and/or data signals. However, the first signal s1 and the second signal s1 are not limited thereto.

The memory device 300 may include the logic die 310 and first to third memory dies 321 to 323. For example, locations of the first to third memory dies 321 to 323, through silicon vias (TSVs), and micro bumps of FIG. 3 may correspond to the locations of the first to third memory dies 221 to 223, the through silicon vias (TSVs), and the micro bumps of FIG. 2. Therefore, additional descriptions of similar components and similar operations will be omitted to avoid redundancy.

The logic die 310 may include a first receiver (Rx1) 311a, a second receiver (Rx2) 311b, a voting circuit 312, test logic 313, a core circuit 314, and a transmitter (Tx) 315. For example, the first receiver (Rx1) 311a, the second receiver (Rx2) 311b, the test logic 313, the core circuit 314, and the transmitter (Tx) 315 included in the logic die 310 of FIG. 3 may correspond to the first receiver (Rx1) 211a, the second receiver (Rx2) 211b, the test logic 213, the core circuit 214, and the transmitter (Tx) 215 included in the logic die 210 of FIG. 2, respectively. Therefore, additional descriptions of similar components and similar operations will be omitted to avoid redundancy.

The first receiver (Rx1) 311a and the second receiver (Rx2) 311b may receive the first signal s1 and the second signal s2, respectively. The first receiver (Rx1) 311a and the second receiver (Rx2) 311b may transmit the first signal s1 and the second signal s2 to the voting circuit 312, respectively.

The voting circuit 312 may include a first logic gate 3121, a second logic gate 3122, a logic circuit 3123, an output circuit 3124, and a multiplexer 3125.

The first logic gate 3121 may perform a first logic operation based on the first signal s1 and the second signal s2. The first logic gate 3121 may output a third signal s3 as a result of the first logic operation. The first logic operation may include an OR operation. The first logic gate 3121 may be an OR gate. However, the first logic gate 3121 is not limited thereto.

The second logic gate 3122 may perform a second logic operation based on the first signal s1 and the second signal s2. The second logic gate 3122 may output a fourth signal s4 as a result of the second logic operation. The second logic operation may include an AND operation. The second logic gate 3122 may be an AND gate. However, the second logic gate 3122 is not limited thereto.

The logic circuit 3123 may perform logic operations based on the first signal s1 and the second signal s2. The logic circuit 3123 may perform different logic operations based on an initial value of the first signal s1 or the second signal s2.

For example, when the initial value of the first signal s1 or the second signal s2 is a first logic value (e.g., 0), the logic circuit 3123 may perform a third logic operation based on the first signal s1 and the second signal s2. The logic circuit 3123 may output a third logic operation result ‘os’ to the output circuit 3124. The logic circuit 3123 may include an OR gate (not illustrated), and the third logic operation may be an OR operation.

For example, when the initial value of the first signal s1 or the second signal s2 is a second logic value (e.g., 1), the logic circuit 3123 may perform a fourth logic operation based on the first signal s1 and the second signal s2. The logic circuit 3123 may output a fourth logic operation result ‘os’ to the output circuit 3124. The logic circuit 3123 may include an AND gate (not illustrated), and the fourth logic operation may be an AND operation.

The output circuit 3124 may receive the third or fourth logic operation result ‘os’ from the logic circuit 3123 depending on the initial value of the first signal s1 or the second signal s2. The output circuit 3124 may be configured to store the third or fourth logic operation result ‘os’ at a rising edge or a falling edge of a reset signal ‘rs’.

The multiplexer 3125 may receive the third signal s3 output from the first logic gate 3121 and the fourth signal s4 output from the second logic gate 3122. The multiplexer 3125 may receive the third or fourth logic operation result ‘os’ from the output circuit 3124 as a selection signal (hereinafter referred to as a ‘mss’).

The multiplexer 3125 may output one of the third signal s3 and the fourth signal s4 to the test logic 313 as a fifth signal s5 based on the selection signal ‘mss’.

For example, when the selection signal ‘mss’ includes the third logic operation result ‘as’, the multiplexer 3125 may output the third signal s3 as the fifth signal s5. For example, when the selection signal ‘mss’ includes the fourth logic operation result ‘os’, the multiplexer 3125 may output the fourth signal s4 as the fifth signal s5.

When the fifth signal s5 received from the voting circuit 312 is normal, the test logic 313 may output a test output signal including information indicating that at least one of the multi-pins is normal to the host 30 through a third pin p3. In this case, the test logic 313 may output the fifth signal s5 received from the voting circuit 312 to the core circuit 314 as a valid signal.

When the fifth signal s5 received from the voting circuit 312 is abnormal, the test logic 313 may output a test output signal including information indicating that all of the multi-pins are faulty pins to the host 30 through the third pin p3. In this case, the test logic 313 may detect faulty pins based on the test input signal and the fifth signal s5 received from the voting circuit 312.

The core circuit 314 may execute an operation corresponding to a valid signal. The core circuit 314 may output an execution result to the test logic 313 and the host 30 through the fourth pin p4.

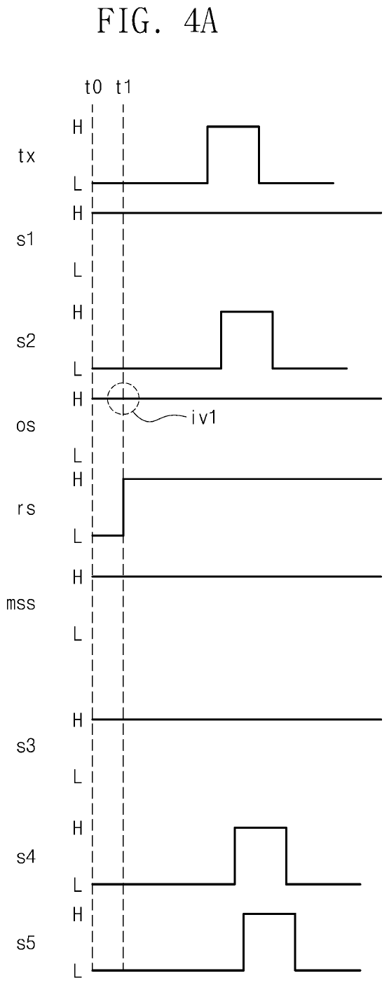

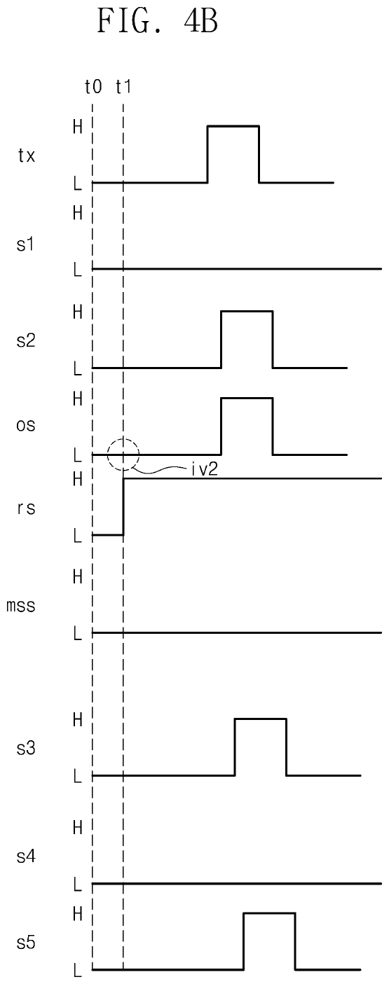

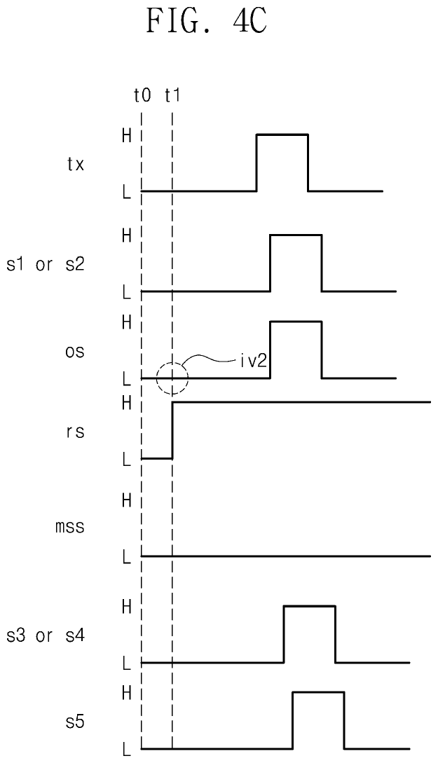

FIG. 4A is a timing diagram illustrating some embodiments of outputting a valid signal when an initial value is a first logic value. As an example, in FIG. 4A, a timing diagram of signals for a case where a first pin is stuck at a logic high level is illustrated. Signals may appear as illustrated in FIG. 4A for a case where a channel electrically connecting between the first pin and the host 30 and the first receiver (Rx1) 311a are also stuck at a logic high level, respectively, as well as the first pin. For example, in FIG. 4A, t0 indicates a first time and t1 indicates a second time.

Referring to FIGS. 3 and 4A, the host 30 may transmit a transmission signal ‘tx’ to the logic die 310 at the first time t0 through the first pin p1 and the second pin p2. When the first pin p1 is stuck at a logic high level, the first signal s1 may have a second logic value (e.g., 1). The second signal s2 may be the same as the transmission signal ‘tx’.

When the initial value of the first signal s1 or the second signal s2 is a first logic value (e.g., 0), the logic circuit 3123 may output the third logic operation result ‘os’ by performing an OR operation based on the first signal s1 and the second signal s2. Accordingly, the third logic operation result ‘os’ may have a second logic value.

The output circuit 3124 may receive the third logic operation result ‘os’ from the logic circuit 3123. At the second time t1, a value iv1 of the third logic operation result ‘os’ may be stored in the output circuit 3124 in response to the rising edge of the applied reset signal. The stored operation result value iv1 may be transmitted to the multiplexer 3125 as the selection signal ‘mss’. In this case, the selection signal ‘mss’ may have a second logic value corresponding to the stored operation result value iv1.

The first logic gate 3121 may perform an OR operation based on the first signal s1 and the second signal s2 to output the third signal s3. In this case, the third signal s3 may have a second logic value. The second logic gate 3122 may output the fourth signal s4 by performing an AND operation on the first signal s1 and the second signal s2.

When the selection signal ‘mss’ includes the third logic operation result ‘os’ having the second logic value, the multiplexer 3125 may select the fourth signal s4 based on the selection signal ‘mss’. The multiplexer 3125 may output the fourth signal s4 to the test logic 313 as the fifth signal s5. Accordingly, a normal signal may be output to the test logic 313 even if the first pin p1 is a faulty pin due to sticking at a logic high level.

FIG. 4B is a timing diagram illustrating some embodiments of outputting a valid signal when an initial value is a first logic value. As an example, in FIG. 4B, a timing diagram of signals for a case where pin 1 is stuck at a logic low level is illustrated. Signals may also appear as illustrated in FIG. 4B for a case where a channel electrically connecting between the first pin and the host 30 and the first receiver (Rx1) 311a are also stuck at a logic low level, respectively, as well as the first pin. Additional descriptions of similar contents to those of FIG. 4A are omitted to avoid redundancy. For example, in FIG. 4B, t0 indicates a first time and t1 indicates a second time.

Referring to FIGS. 3 and 4B, when the first pin p1 is stuck at a logic low level, the first signal s1 may have a first logic value (e.g., 0). The second signal s2 may be the same as the transmission signal ‘tx’.

The logic circuit 3123 may perform an OR operation based on the first signal s1 and the second signal s2 to output the third logic operation result ‘os’. Accordingly, the third logic operation result ‘os’ may include the second signal s2.

At the second time t1, a value iv2 of the third logic operation result ‘os’ may be stored in the output circuit 3124 in response to the rising edge of the applied reset signal. The stored operation result value iv2 may be transmitted to the multiplexer 3125 as the selection signal ‘mss’. In this case, the selection signal ‘mss’ may have a first logic value corresponding to the stored operation result value iv2.

The first logic gate 3121 may perform an OR operation based on the first signal s1 and the second signal s2 to output the third signal s3. The second logic gate 3122 may output the fourth signal s4 by performing an AND operation on the first signal s1 and the second signal s2. In this case, the fourth signal s4 may have a first logic value.

When the selection signal ‘mss’ includes the third logic operation result ‘os’ having the first logic value, the multiplexer 3125 may select the third signal s3 based on the selection signal ‘mss’. The multiplexer 3125 may output the third signal s3 to the test logic 313 as the fifth signal s5. Accordingly, a normal signal may be output to the test logic 313 even if the first pin p1 is a faulty pin due to sticking at a logic low level.

FIG. 4C is a timing diagram illustrating a third embodiment of outputting a valid signal when an initial value is a first logic value. For example, in FIG. 4C, a timing diagram of signals for a case where both the first pin and the second pin are normal is illustrated. Additional descriptions of similar contents to those of FIG. 4A will be omitted to avoid redundancy. For example, in FIG. 4C, t0 indicates a first time and t1 indicates a second time.

Referring to FIGS. 3 and 4C, the transmission signal ‘tx’, the first signal s1, and the second signal s2 transmitted by the host may be the same signal at the first time t0.

The logic circuit 3123 may perform an OR operation based on the first signal s1 and the second signal s2 to output the third logic operation result ‘os’. Accordingly, the third logic operation result ‘os’ may include the first signal s1 and the second signal s2.

At the second time t1, the value iv2 of the third logic operation result ‘os’ may be stored in the output circuit 3124 in response to the rising edge of the applied reset signal. The stored operation result value iv2 may be transmitted to the multiplexer 3125 as the selection signal ‘mss’. In this case, the selection signal ‘mss’ may have a first logic value corresponding to the stored operation result value iv2.

The first logic gate 3121 may perform an OR operation based on the first signal s1 and the second signal s2 to output the third signal s3. The second logic gate 3122 may output the fourth signal s4 by performing an AND operation on the first signal s1 and the second signal s2.

When the selection signal ‘mss’ includes the third logic operation result ‘os’ having the first logic value, the multiplexer 3125 may select the third signal s3 based on the selection signal ‘mss’. The multiplexer 3125 may output the third signal s3 to the test logic 313 as the fifth signal s5.

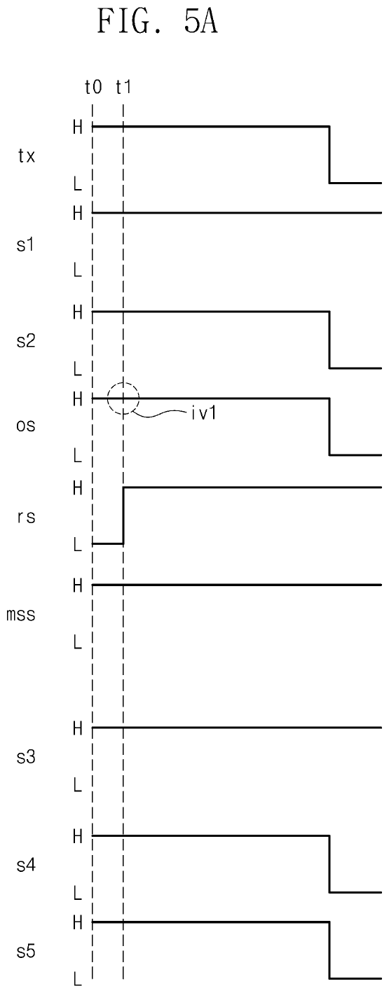

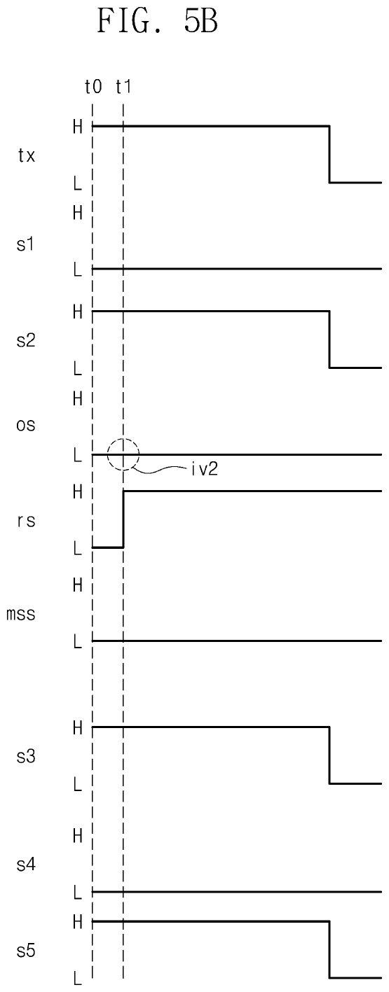

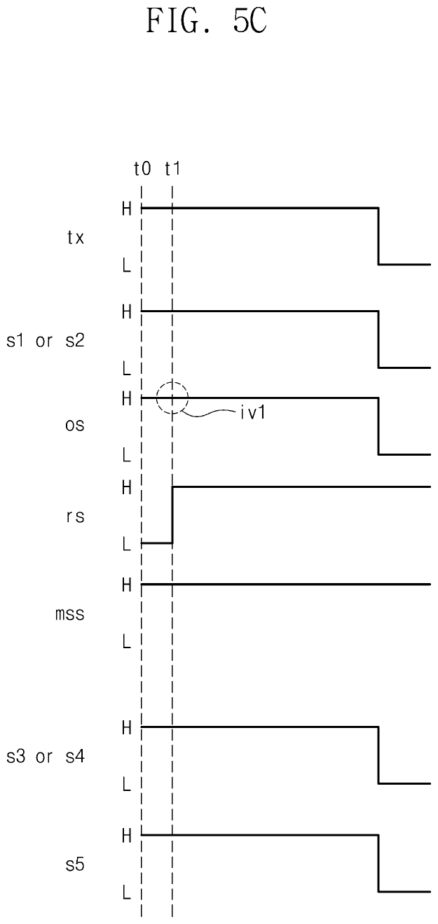

FIG. 5A is a timing diagram illustrating some embodiments of outputting a valid signal when an initial value is a second logic value. As an example, in FIG. 5A, a timing diagram of signals for a case where a first pin is stuck at a logic high level is illustrated. Signals may appear as illustrated in FIG. 5A for a case where the channel electrically connecting between the first pin and the host 30 and the first receiver (Rx1) 311a are also stuck at a logic high level, respectively, as well as the first pin. For example, in FIG. 5A, t0 indicates a first time and t1 indicates a second time.

Referring to FIGS. 3 and 5A, the host 30 may transmit the transmission signal ‘tx’ to the logic die 310 through the first pin p1 and the second pin p2 at the first time t0.

In FIG. 5A, the transmission signal ‘tx’ transmitted from the host 30 may be a different signal from the transmission signal ‘tx’ of FIG. 4A. For example, in FIG. 5A, the transmission signal ‘tx’ transmitted from the host 30 may have an initial value of a second logic value (e.g., 1).

When the first pin p1 is stuck at a logic high level, the first signal s1 may have a second logic value. The second signal s2 may be the same as the transmission signal ‘tx’.

When the initial value of the first signal s1 or the second signal s2 is the second logic value, the logic circuit 3123 may perform an AND operation based on the first signal s1 and the second signal s2 to output the fourth logic operation result ‘os’. Accordingly, the fourth logic operation result ‘os’ may include the second signal s2.

The output circuit 3124 may receive the fourth logic operation result ‘os’ from the logic circuit 3123. At the second time t1, the value iv1 of the fourth logic operation result ‘os’ may be stored in the output circuit 3124 in response to the rising edge of the applied reset signal. The stored operation result value iv1 may be transmitted to the multiplexer 3125 as the selection signal ‘mss’. In this case, the selection signal ‘mss’ may have a second logic value corresponding to the stored operation result value iv1.

The first logic gate 3121 may perform an OR operation on the first signal s1 and the second signal s2 to output the third signal s3. In this case, the third signal s3 may have a second logic value. The second logic gate 3122 may output the fourth signal s4 by performing an AND operation on the first signal s1 and the second signal s2.

When the selection signal ‘mss’ includes the third logic operation result ‘os’ having the second logic value, the multiplexer 3125 may select the fourth signal s4 based on the selection signal ‘mss’. The multiplexer 3125 may output the fourth signal s4 to the test logic 313 as the fifth signal s5. Accordingly, a normal signal may be output to the test logic 313 even if the first pin p1 is a faulty pin due to sticking at a logic high level.

FIG. 5B is a timing diagram illustrating some embodiments of outputting a valid signal when an initial value is a second logic value. As an example, in FIG. 5B, a timing diagram of signals for a case where the first pin p1 is stuck at a logic low level is illustrated. Signals may appear as illustrated in FIG. 5B for a case where the channel electrically connecting between the first pin and the host 30 and the first receiver (Rx1) 311a are also stuck at a logic low level, respectively, as well as the first pin. For example, in FIG. 5B, t0 indicates a first time and t1 indicates a second time.

Referring to FIGS. 3 and 5B, when the first pin p1 is stuck at a low level, the first signal s1 may have a first logic value (e.g., 0). The second signal s2 may be the same as the transmission signal ‘tx’.

The logic circuit 3123 may perform an AND operation based on the first signal s1 and the second signal s2 to output the fourth logic operation result ‘os’. Accordingly, the fourth logic operation result ‘os’ may have a first logic value.

At the second time t1, the value iv2 of the fourth logic operation result ‘os’ may be stored in the output circuit 3124 in response to the rising edge of the applied reset signal. The stored operation result value iv2 may be transmitted to the multiplexer 3125 as the selection signal ‘mss’. In this case, the selection signal ‘mss’ may have a first logic value corresponding to the stored operation result value iv2.

The first logic gate 3121 may perform an OR operation on the first signal s1 and the second signal s2 to output the third signal s3. The second logic gate 3122 may output the fourth signal s4 by performing an AND operation on the first signal s1 and the second signal s2. In this case, the fourth signal s4 may have a first logic value.

When the selection signal ‘mss’ includes the fourth logic operation result ‘os’ having the first logic value, the multiplexer 3125 may select the third signal s3 based on the selection signal ‘mss’. The multiplexer 3125 may output the third signal s3 to the test logic 313 as the fifth signal s5. Accordingly, a normal signal may be output to the test logic 313 even if the first pin p1 is a faulty pin due to sticking at a logic low level.

FIG. 5C is a timing diagram illustrating some embodiments of outputting a valid signal when an initial value is a second logic value. For example, in FIG. 4C, a timing diagram of signals for a case where both the first pin and the second pin are normal is illustrated. Additional descriptions of similar contents to those of FIG. 4A will be omitted to avoid redundancy. For example, in FIG. 5C, t0 indicates a first time and t1 indicates a second time.

Referring to FIGS. 3 and 5C, the transmission signal ‘tx’, the first signal s1, and the second signal s2 transmitted by the host at the first time t0 may be the same signal.

The logic circuit 323 may perform an AND operation based on the first signal s1 and the second signal s2 to output the fourth logic operation result ‘os’. Accordingly, the fourth logic operation result ‘os’ may include the first signal s1 and the second signal s2.

At the second time t1, the value iv1 of the fourth logic operation result ‘os’ may be stored in the output circuit 3124 in response to the rising edge of the applied reset signal. The stored operation result value iv1 may be transmitted to the multiplexer 3125 as the selection signal ‘mss’. In this case, the selection signal ‘mss’ may have a second logic value corresponding to the stored operation result value iv1.

The first logic gate 3121 may perform an OR operation on the first signal s1 and the second signal s2 to output the third signal s3. The second logic gate 3122 may output the fourth signal s4 by performing an AND operation on the first signal s1 and the second signal s2.

When the selection signal ‘mss’ includes the fourth logic operation result ‘os’ having the second logic value, the multiplexer 3125 may select the fourth signal s4 based on the selection signal ‘mss’. The multiplexer 3125 may output the fourth signal s4 to the test logic 313 as the fifth signal s5.

FIG. 6 is a diagram illustrating a detailed configuration of a memory device, according to some embodiments of the present disclosure. For example, FIG. 6 illustrates a configuration in which a logic die 610 and a first memory die (HBM DRAM Die) 620 transmit and receive signals through four ports po1 to po4 that electrically connect the logic die 610 to the first memory die 620. However, the number of ports may be five or more.

For example, FIG. 6 illustrates a configuration in which the first memory die 620 flexibly votes valid signals. However, it is not limited thereto, and one of second and third memory dies 630 and 640 may flexibly vote valid signals.

In addition to the micro bumps illustrated in FIG. 1, the four ports po1 to po4 illustrated in FIG. 6 are connected to the logic die 610 and the first memory die 620, respectively, and the logic die 610 and the first memory die 620 may communicate with each other based on the four ports po1 to po4.

Referring to FIGS. 3 and 6, a memory device 600 may include the logic die 610 and the first to third memory dies 620 to 640. For example, locations of the first to third memory dies 620 to 640, through silicon vias (TSVs), and micro bumps of FIG. 6 may correspond to the locations of the first to third memory dies 321 to 323, the through silicon vias (TSVs), and the micro bumps of FIG. 3. Therefore, additional descriptions of similar components and similar operations will be omitted to avoid redundancy.

The logic die 610 may include a transmitter (Tx) 615. For example, the transmitter (Tx) 615 of FIG. 6 may correspond to the transmitter (Tx) 315 of FIG. 3. The logic die 610 may transmit an address and data received from the host to the first memory die 620 through the transmitter (Tx) 615. The logic die 610 may receive data from the first memory die 620.

The transmitter (Tx) 615 may transmit the first signal s1 and the second signal s2 to the first memory die 620 through the first port po1 and the second port po2. The first signal s1 and the second signal s2 may be the same or similar signal.

The first memory die 620 may include a first receiver (Rx1) 621a, a second receiver (Rx2) 621b, a voting circuit 622, test logic 623, a core circuit 624, and a transmitter (Tx) 625.

The first receiver (Rx1) 621a and the second receiver (Rx2) 621b may receive the first signal s1 and the second signal s2, respectively. The first receiver (Rx1) 621a and the second receiver (Rx2) 621b may transmit the first signal s1 and the second signal s2 to the voting circuit 622, respectively.

The voting circuit 622 may include a first logic gate 6221, a second logic gate 6222, a logic circuit 6223, an output circuit 6224, and a multiplexer 6225. For example, the first logic gate 6221, the second logic gate 6222, the logic circuit 6223, the output circuit 6224, and the multiplexer 6225 included in the voting circuit 622 of FIG. 6 may correspond to the first logic gate 3121, the second logic gate 3122, the logic circuit 3123, the output circuit 3124, and the multiplexer 3125 included in the voting circuit 312 of the FIG. 3, respectively. Therefore, additional descriptions of similar components and similar operations will be omitted to avoid redundancy.

In detail, a configuration for flexibly voting valid signals among a plurality of signals received from the host 30 in the logic die 310 of FIG. 3 may correspond to a configuration of flexibly voting valid signals among a plurality of signals received from the logic die 610 in the first memory die 620 of FIG. 6.

When the fifth signal s5 received from the voting circuit 622 is normal, the test logic 623 may output a test output signal including information indicating that at least one of the first and second ports po1 and po2 is normal to the logic die 610 through the third port po3. In this case, the test logic 630 may output the fifth signal s5 received from the voting circuit 622 to the core circuit 624 as a valid signal.

When the fifth signal s5 received from the voting circuit 622 is abnormal, the test logic 623 may output a test output signal indicating that all of the multi-ports are faulty ports to the logic die 610 through the third port po3. In this case, the test logic 623 may detect faulty ports based on the test input signal and the fifth signal s5 received from the voting circuit 622.

The core circuit 624 included in the first memory die 620 may include a memory cell array (not illustrated) and a decoder (not illustrated). The core circuit 624 may perform an operation corresponding to a valid signal.

For example, when a valid signal includes a read command and address, the core circuit 624 may decode the read command and address. In this case, the core circuit 624 may output data of memory cells corresponding to the address to the logic die 610 through the fourth port po4.

For example, when a valid signal includes a write command and address, the core circuit 624 may decode the write command and address. The core circuit 624 may receive data from the logic die 610 through the fourth port po4. The core circuit 624 may write data to memory cells corresponding to addresses.

For example, when a write command and an address are transmitted to the first memory die 620 and a valid signal is a data signal, the core circuit 624 may decode the write command and the address and may write data to memory cells corresponding to the addresses.

The core circuit 624 may transmit a result of performing an operation corresponding to the valid signal to the test logic 623.

The transmitter (Tx) 625 may receive the first signal s1 and the second signal s2 from the logic die 610 through the first and second ports po1 and po2. The transmitter (Tx) 625 may transmit the first signal s1 and the second signal s2 to the second memory die 630.

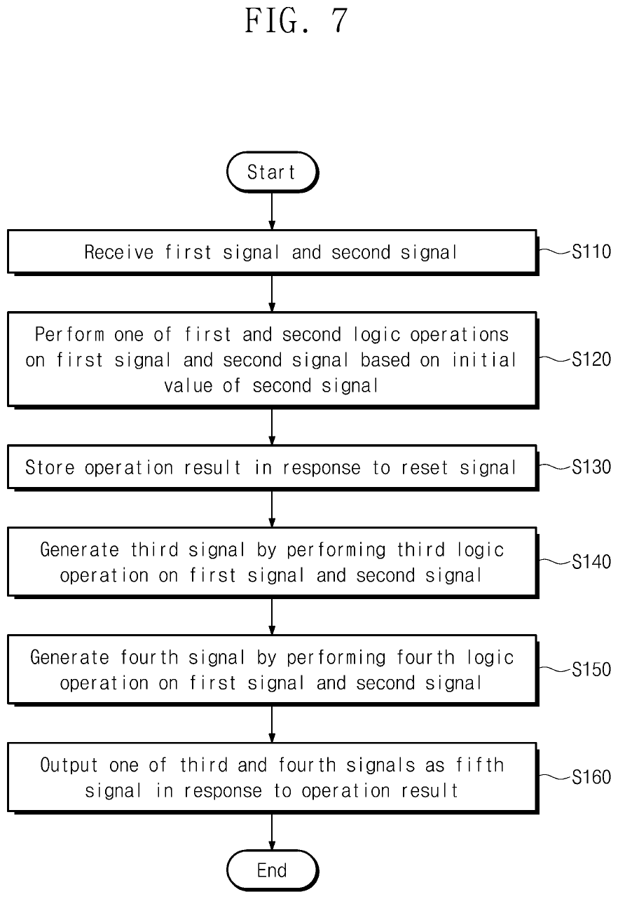

FIG. 7 is a flowchart illustrating an operating method for outputting a valid signal by a memory device. Referring to FIGS. 1, 3, 6, and 7, in operation S110, the memory device 100 may receive the first signal and the second signal from the host 30.

The first signal and the second signal may be transmitted to the logic die through a plurality of pins and may be transmitted to the memory die through a plurality of ports. The first signal and the second signal may be the same signal.

In operation S120, the memory device 100 may perform one of first and second logic operations on the first signal and the second signal based on the initial value of the second signal. The memory device 100 may perform an OR operation when the initial value of the second signal is a first logic value (e.g., 0), and may perform an AND operation when the initial value of the second signal is a second logic value (e.g., 1).

In operation S130, the memory device 100 may store an operation result in response to a reset signal. The memory device 100 may use the stored operation result to vote one signal among signals output from different logic gates.

In operation S140, the memory device 100 may generate a third signal by performing a third logic operation on the first signal and the second signal. The third logic operation may include an OR operation.

In operation S150, the memory device 100 may generate a fourth signal by performing a fourth logic operation on the first signal and the second signal. The fourth logic operation may include an AND operation.

In operation S160, the memory device 100 may output one of the third signal and the fourth signal as a fifth signal in response to the operation result stored in operation S130. The memory device 100 may output the third signal as the fifth signal when the stored operation result has the first logic value. The memory device 100 may output the fourth signal as the fifth signal when the stored operation result has the second logic value.

According to some embodiments of the present disclosure, a memory device, an electronic device, and a method of operating the memory device according to some embodiments of the present disclosure may vote signals output through different logic gates as valid signals, according to error types of some pins among multi-pins. Accordingly, the memory device may operate based on valid signals regardless of error types of some pins.

The above descriptions are specific embodiments for carrying out the present disclosure. Embodiments in which a design is changed simply or which are easily changed may be included in the present disclosure as well as embodiments described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a logic circuit configured to receive a first signal and a second signal from an external host, and to perform a first logic operation or a second logic operation based on an initial value of the second signal;
an output circuit configured to receive a first logic operation result or a second logic operation result from the logic circuit, and configured to store the first logic operation result or the second logic operation result that was received, in response to a reset signal;
a first logic gate configured to receive the first signal and the second signal, and configured to perform a third logic operation on the first signal and the second signal to output a third signal;
a second logic gate configured to receive the first signal and the second signal, and configured to perform a fourth logic operation on the first signal and the second signal to output a fourth signal; and
a multiplexer configured to receive the third signal and the fourth signal, configured to receive the first logic operation result or the second logic operation result that was stored from the output circuit, and configured to output the third signal or the fourth signal as a fifth signal in response to the first logic operation result or the second logic operation result that was received by the multiplexer.

2. The memory device of claim 1, wherein the logic circuit is configured to perform the first logic operation based on the initial value of the second signal being a first logic value.

3. The memory device of claim 2, wherein, when the logic circuit is configured to output a first value to the output circuit as a result of the first logic operation, the output circuit is configured to store the first value in response to the reset signal, and the multiplexer is configured to output the fourth signal as the fifth signal.

4. The memory device of claim 2, wherein, when the logic circuit is configured to output a second value to the output circuit as a result of the first logic operation, the output circuit is configured to store the second value in response to the reset signal, and the multiplexer is configured to output the third signal as the fifth signal.

5. The memory device of claim 1, wherein the logic circuit is configured to perform the second logic operation based on the initial value of the second signal being a second logic value.

6. The memory device of claim 5, wherein, when the logic circuit is configured to output a first value to the output circuit as a result of the second logic operation, the output circuit is configured to store the first value in response to the reset signal, and the multiplexer is configured to output the fourth signal as the fifth signal.

7. The memory device of claim 5, wherein, when the logic circuit is configured to output a second value to the output circuit as a result of the second logic operation, the output circuit is configured to store the second value in response to the reset signal, and the multiplexer is configured to output the third signal as the fifth signal.

8. The memory device of claim 1, wherein the first logic operation and the third logic operation include an OR operation, and
wherein the second logic operation and the fourth logic operation include an AND operation.

9. A method of operating a memory device including a logic circuit, an output circuit, a first logic gate, a second logic gate, and a multiplexer, the method comprising:
receiving, by the logic circuit, a first signal and a second signal from an external host;
performing, by the logic circuit, a first logic operation or a second logic operation on the first signal and the second signal based on an initial value of the second signal;
receiving, by the output circuit, an operation result from the logic circuit, and storing the operation result in response to a reset signal;
outputting, by the first logic gate, a third signal by performing a third logic operation on the first signal and the second signal;
outputting, by the second logic gate, a fourth signal by performing a fourth logic operation on the first signal and the second signal; and
outputting, by the multiplexer, the third signal or the fourth signal as a fifth signal in response to the operation result.

10. The method of claim 9, wherein the first logic operation by the logic circuit is performed based on the initial value of the second signal being a first logic value.

11. The method of claim 10,
when the logic circuit outputs a first value to the output circuit as a result of the first logic operation, performing operations comprising:
storing, by the output circuit, the first value in response to the reset signal; and
outputting, by the multiplexer, the fourth signal as the fifth signal.

12. The method of claim 10,
when the logic circuit outputs a second value to the output circuit as a result of the first logic operation, performing operations comprising:
storing, by the output circuit, the second value in response to the reset signal; and
outputting, by the multiplexer, the third signal as the fifth signal.

13. The method of claim 9, wherein the second logic operation by the logic circuit is performed based on the initial value of the second signal being a second logic value.

14. The method of claim 13,
when the logic circuit outputs a first value to the output circuit as a result of the second logic operation, performing operations comprising:
storing, by the output circuit, the first value in response to the reset signal; and
outputting, by the multiplexer, the fourth signal as the fifth signal.

15. The method of claim 13,
when the logic circuit outputs a second value to the output circuit as a result of the second logic operation, performing operations comprising:
storing, by the output circuit, the second value in response to the reset signal; and
outputting, by the multiplexer, the third signal as the fifth signal.

16. The method of claim 9, wherein the first logic operation and the third logic operation include an OR operation, and
wherein the second logic operation and the fourth logic operation include an AND operation.

17. An electronic device comprising:
an external host; and
a memory device configured to receive a first signal and a second signal from the external host, and
wherein the memory device comprises:
a logic circuit configured to perform a first logic operation or a second logic operation based on an initial value of the second signal;
an output circuit configured to receive a first logic operation result or a second logic operation result from the logic circuit, and configured to store the first logic operation result or the second logic operation result in response to a reset signal;
a first logic gate configured to perform a third logic operation on the first signal and the second signal to output a third signal;
a second logic gate configured to perform a fourth logic operation on the first signal and the second signal to output a fourth signal; and
a multiplexer configured to receive the third signal and the fourth signal, configured to receive the first logic operation result or the second logic operation result that was stored from the output circuit, and configured to output the third signal or the fourth signal as a fifth signal in response to the first logic operation result or the second logic operation result that was received by the multiplexer.

18. The electronic device of claim 17, wherein the logic circuit is configured to perform the first logic operation based on the initial value of the second signal being a first logic value,
wherein the logic circuit is configured to output a first value or a second value as a result of the first logic operation to the output circuit,
wherein the output circuit is configured to store the first value or the second value in response to the reset signal, and
wherein the multiplexer is configured to output the fourth signal as the fifth signal in response to the first value and is configured to output the third signal as the fifth signal in response to the second value.

19. The electronic device of claim 17, wherein the logic circuit is configured to perform the second logic operation based on the initial value of the second signal being a second logic value,
wherein the logic circuit is configured to output one of a first value or a second value as a result of the second logic operation to the output circuit,
wherein the output circuit is configured to store one of the first value or the second value in response to the reset signal, and
wherein the multiplexer is configured to output the fourth signal as the fifth signal in response to the first value and is configured to output the third signal as the fifth signal in response to the second value.

20. The electronic device of claim 17, wherein the first logic operation and the third logic operation include an OR operation, and
wherein the second logic operation and the fourth logic operation include an AND operation.
